(19) United States
(12) Patent Application Publication
(10) Pub. No.: US 2026/0341316 A1
(43) Pub. Date: Oct. 29, 2026

(54) MEMORY DEVICE WITH FLYING BIT LINES

(71) Applicant: Taiwan Semiconductor Manufacturing Company, Ltd., Hsinchu (TW)

(72) Inventors: Jacklyn CHANG, San Ramon, CA (US); Derek C. TAO, Fremont, CA (US)

(21) Appl. No.: 19/351,035

(22) Filed: Oct. 6, 2025

Related U.S. Application Data
(60) Provisional application No. 63/793,328, filed on Apr. 23, 2025.

(51) Int. Cl. G11C 5/06; G11C 11/419; H10B 10/00

(52) U.S. Cl. CPC G11C 5/063; G11C 11/419; H10B 10/12; H10B 10/18

(57) ABSTRACT

A memory device with a flying bit line is provided. The memory device includes an array having a plruality of columns. Each column of the plurality of columns includes a first pair of read bit lines connected to a first portion of memory cells of a top region of the column, a second pair of read bit lines connected to a second portion of memory cells of a bottom region of the column, and a first pair of flying read bit lines. The memory device further includes a connection cell positioned between the top region and the bottom region. The connection cell includes vertical interconnects the connect the first pair of read bit lines to the first pair of flying read bit lines.

### CROSS-REFERENCE TO RELATED APPLICATION

This application claims priority to and the benefit of U.S. Provisional Application No. 63/793,328, filed Apr. 23, 2025, which is incorporated herein by reference in its entirety for all purposes.

### BACKGROUND

A semiconductor memory device is an electronic data storage device implemented on a semiconductor-based integrated circuit. A semiconductor memory device has various types, and has faster access times than other data storage technologies. For example, a byte of data can often be written to or read from a semiconductor memory device within a few nanoseconds, while access times for rotating storage, such as hard disks, is in the range of milliseconds. For these reasons, among others, the semiconductor memory device is used as a primary storage mechanism for computers to hold data that the computers are currently working on, among other uses.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a memory cell, in accordance with some embodiments.

FIG. 2 illustrates a nth column of an array of a memory device, in accordance with example embodiments.

FIG. 3 illustrates a top view of a first routing layer of a connection cell, of the memory device in accordance with example embodiments.

FIG. 4 illustrates a top view of a second routing layer of the connection cell, in accordance with example embodiments.

FIG. 5 illustrates a cross-section view of the connection cell, in accordance with example embodiments.

FIG. 6 illustrates a top view of a fourth routing layer of the connection cell, in accordance with example embodiments.

FIG. 7 illustrates a top view of a first routing layer of the connection cell, in accordance with example embodiments.

FIG. 8 illustrates a nth column of an array of another memory device, in accordance with example embodiments.

FIG. 9 illustrates a nth column of an array of yet another memory device, in accordance with example embodiments.

FIG. 10 is a flow diagram illustrating of a first method for forming a memory device, in accordance with some embodiments.

FIG. 11 is a flow diagram illustrating a second method for forming any of memory device, in accordance with some embodiments.

FIG. 12 is a block diagram of a layout system, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

One type of integrated circuit memory is a Static Random Access Memory (SRAM) device. A SRAM is a type of a semiconductor memory device that stores data in the form of bits using bistable circuitry without the need for refreshing. A SRAM cell may be referred to as a bit cell because it stores a bit of information. A SRAM cell is bistable, meaning it can maintain its state indefinitely as long as an adequate power is supplied. A SRAM can operate at a higher speed and lower power dissipation, so computer cache memories use SRAMs. Other applications include embedded memories and networking equipment memories. There are several types of SRAM cells (e.g., 6-transistor (6T) SRAM, dual port 8-transistor (8T) SRAM, a two read one write (2R1W) 10 transistor (10T), etc.).

A memory array generally includes multiple bit cells arranged in rows and columns. Each bit cell in a memory array may include connections to a power supply voltage and to a reference voltage. Bit Lines (BLs) may be used for accessing a bit cell with a Word Line (WL) controlling connections to the BLs. A WL may be coupled to a corresponding set of the bit cells that are arranged in a row of a memory array with different WLs provided for respective rows, and a BL may be coupled to a corresponding set of the bit cells that are arranged in a column of a memory array with different BLs provided for respective columns. Typically, the bit lines extend in one direction (parallel to a first axis) and the word lines extend in a second direction (parallel to a second axis) perpendicular to the first direction.

Each bit in the SRAM cell is stored on four of the transistors, which form two cross-coupled inverters. These transistors are typically implemented as Complementary Metal-oxide-Semiconductor (CMOS) technology, where each inverter consists of one p-type Metal-Oxide-Semiconductor (PMOS) and one n-type metal-oxide-semiconductor (NMOS) transistor. The gates of the PMOS and NMOS transistors are connected to each other, creating a feedback loop. This cross-coupled structure allows the cell to store a single bit of data (0 or 1) by latching the complementary values on the bit-lines.

A typical memory cell of a SRAM memory device uses 6 transistors (6T) connected between an upper reference potential and a lower reference potential (typically ground) such that one of two storage nodes can be occupied by the information to be stored, with the complementary information stored at the other storage node. Each bit in the SRAM cell is stored on four of the transistors, which form the two cross-coupled inverters. The other two transistors of a 6T memory cell are connected to a memory cell WL to control access (i.e. “access transistors”) to the memory cell during read and write operations by selectively connecting the memory cell to its BLs. In a read operation, for example, the BLs are pre-charged to a predefined threshold voltage. When the WL is enabled, a sense amplifier connected to the BLs senses and outputs stored information.

Another type of SRAM cell is a 2R1W cell, which is also referred to as a 10 transistor (10T) cell. For example, a 2R1W 10T SRAM cell includes a pair of read pull-down NMOS transistors and a pair of read pass-gate NMOS transistors. The gates of the read pull-down transistors are connected to respective data nodes. A source/drain (SD) region of each of the read pass-gate transistors is connected to a respective read BL. The gates of the read pass-gate transistors are connected to respective read WLs. An example 2R1W cell is discussed in greater detail in the following sections of the disclosure.

A 2R1W cell allows two memory accesses to occur simultaneously, or nearly simultaneously, over two ports each. The 2R1W cell memory device comprises one or more banks of memory cells, each bank of memory cells including a plurality of 10T memory cells arranged in rows and columns. Two WLs correspond to the two ports and extend along each row, being electrically coupled to each memory cell in the row. Two pairs of complementary BLs (BBLs) correspond to the two ports and extend along each column and are electrically coupled to each memory cell in the column. The WLs of each port provide access to the memory cells on a line-by-line basis, and the BBLs of each port enable data states to be written to or read from access memory cells on a column-by-column basis.

A bank of memory cells often has between 128 lines and 512 lines. However, this results in long BLs and therefore high loads on the BLs. The high loads on the BLs may in turn lead to high minimum read voltages and high minimum write voltages on the BLs. Read voltages and write voltages below the high minimum read voltages and the high minimum write voltages result in instability in reading from the memory cells and writing to them. In addition, the high minimum read voltages and the high minimum write voltages can in turn lead to a high dynamic power consumption. One solution to mitigate the effects of long BLs is to use smaller banks of memory cells. For example, a large bank of 128-row memory cells may be replaced by two small banks of 64-row memory cells. However, increasing the number of banks increases the area used by the memory cells, which can lead to higher costs.

In addition, the BLs often run parallel to each other and are separated by a small distance. With the improvement of technology and reduction of feature sizes, the distances between adjacent BLs will become even smaller. However, this close spacing results in a significant amount of capacitive coupling, especially for long BLs that extend continuously along an entire column of a bank. The capacitive coupling, in turn, may lead to slow read and write times and may further lead to a degradation of signal-to-noise ratios.

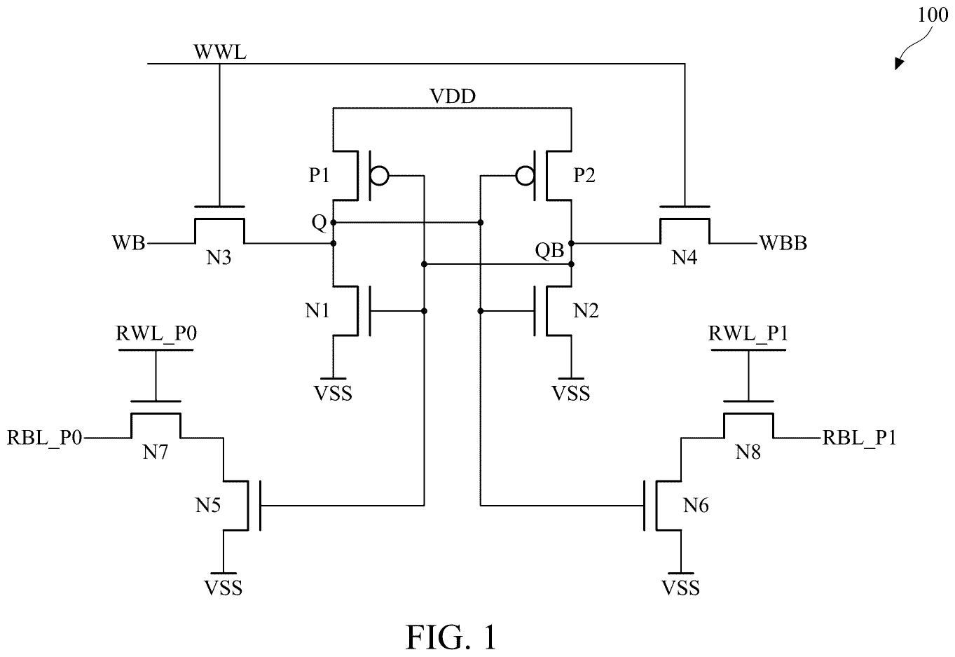

In view of the foregoing, the present disclosure is directed to a flying bit lines and a connection cell to connect the bit lines to the flying bit lines. FIG. 1 illustrates a schematic diagram of memory cell 100 that is implemented, for example, as a 2R1W cell and as a 10T SRAM cell. As shown in FIG. 1, memory cell 100 includes NMOS transistors N₁, N₂, N₃, N₄, N₅, N₆, N₇, N₈ and PMOS transistors P₁, P₂. A gate of each of the transistors N₃, N4 are coupled to a write WL (WWL). A drain/source of the transistor N₃ is coupled to a write BL (WB), and a source/drain of the transistor N₃ is coupled to a node Q. A drain/source of the transistor N₄ is coupled to a complementary WLB (WBB), and a source/drain of the transistor N₄ is coupled to a node QB. The node QB is complementary to the node Q. The transistors N₃, N₄ operate as electrical switches and allow the WB to electrically couple to or decouple from the node Q and allow the WBB to electrically couple to or decouple from the node QB based on a voltage applied to the WWL. For example, based on a supply voltage VDD corresponding to a high state (or logic value ‘1’) applied to the WWL, the transistor N₃ is enabled to electrically couple the WB to the nod Q and the transistor N₄ is enabled to electrically couple the WBB to the node QB. In another example, based on a ground voltage VSS corresponding to a low state (or logic value ‘0’) applied to the WWL, the transistor N₃ is disabled to electrically decouple the WB from the node Q and the transistor N₄ is disabled to electrically decouple the WBB from the node QB.

The transistor N₁ includes a source/drain coupled to a first supply voltage rail supplying the ground voltage VSS, a gate coupled to the node QB, and a drain/source coupled to the node Q. The transistor P₁ includes a source/drain coupled to a second supply voltage rail supplying the supply voltage VDD, a gate coupled to the node QB, and a drain/source coupled to the node Q. The transistor N₂ includes a source/drain coupled to the first supply voltage rail supplying the ground voltage VSS, a gate coupled to the node Q, and a drain/source coupled to the node QB. The transistor P₂ includes a source/drain coupled to the second supply voltage rail supplying the supply voltage VDD, a gate coupled to the node Q, and a drain/source coupled to the node QB. The transistor N₁ and the transistor P₁ operate as a first inverter, and the transistor N₂ and the transistor P₂ operate as a second inverter, cross-coupled to each other. The cross-coupled inverters may sense and amplify a difference in voltages at the nodes Q, QB. When writing data, the cross-coupled inverters may sense voltages at the nodes Q, QB provided through the transistors N₃, N₄ and amplify a difference in voltages at the WB and WBB. For example, the cross-coupled inverters sense a voltage 0.5 V at the node Q and a voltage 0.4V at the node QB, and amplify a difference in the voltages at the nodes Q, QB through a positive feedback (or a regenerative feedback) such that the voltage at the node Q becomes the supply voltage VDD (e.g., 1V) and the voltage at the node QB becomes the ground voltage VSS (e.g. 0V). The amplified voltages at the nodes Q, QB may be provided to the WB, WBB through the transistors N₃, N₄, respectively for reading.

The transistor N₅ includes a source/drain coupled to the first supply voltage rail supplying the ground voltage VSS, a gate coupled to the node QB, and a drain/source coupled to a source/drain of the transistor N₇. A drain/source of the transistor N₇ is coupled to a first read BL (RBL_P0) and a gate of the transistor N₇ is connected to a first read WL (RWL_P0). The transistor N₅ and the transistor N₇ together form a first read port for the 2R1W cell.

The transistor N₆ includes a source/drain coupled to the first supply voltage rail supplying the ground voltage VSS, a gate coupled to the node Q, and a drain/source coupled to a source/drain of the transistor N₈. A drain/source of the transistor N₈ is coupled to a second read BL (RBL_P1) and a gate of the transistor N₈ is connected to a second read WL (RWL_P1). The transistor N₅ and the transistor N₇ together form a first read port for the 2R1W cell.

The transistors N₇, N₈ operate as electrical switches and allow the RBL_P1 to electrically couple to or decouple from the node Q and allow the RBL_P0 to electrically couple to or decouple from the node QB based on a voltage applied to the RWL_P1 and RWL_P0 repetitively. For example, based on a supply voltage VDD corresponding to a high state (or logic value ‘1’) applied to the RWL_P0, the transistor N₇ is enabled to electrically couple the RBL_P0 to the nod QB. Similarly, based on a supply voltage VDD corresponding to a high state applied to the RWL_P1, and the transistor N₈ is enabled to electrically couple the RBL_P1 to the node Q. In another example, based on a ground voltage VSS corresponding to a low state (or logic value ‘0’) applied to the RWL_P0 the transistor N₇ is disabled to electrically decouple the RBL_P0 from the node QB. Similarly, based on a ground voltage VSS corresponding to a low state applied to the RWL_P1 the transistor N₈ is disabled to electrically decouple the RBL_P1 from the node Q.

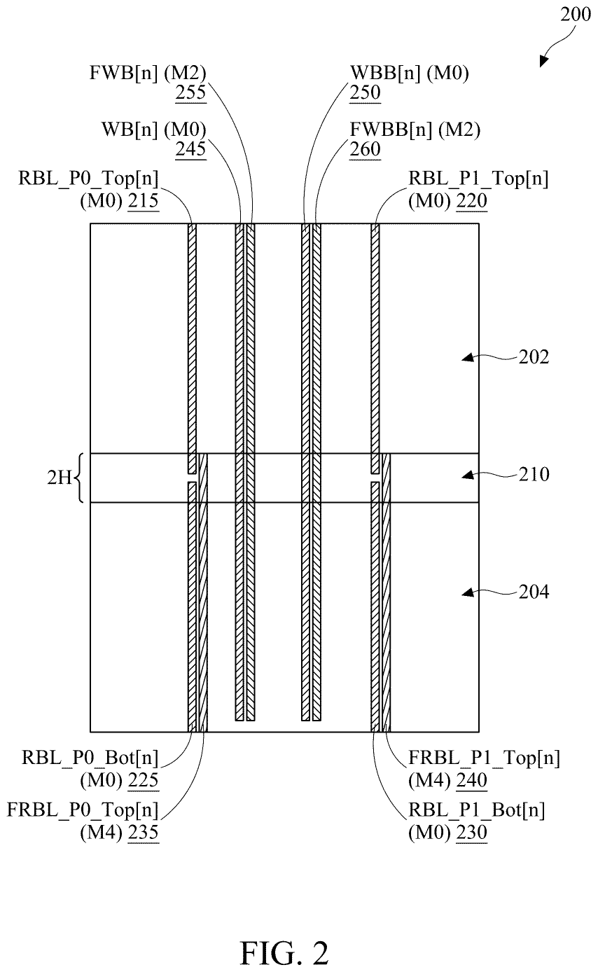

FIG. 2 illustrates a nth column of an array of a memory device 200 in accordance with example embodiments. The array of memory device 200 includes a plurality of columns and a plurality of rows. In each of the plurality of columns may include a first plurality of memory cells for example, a first plurality of 2R1W cells described above with reference to FIG. 1. Each of the plurality of rows may include a second plurality of memory cells, for example, a second plurality of 2R1W cells described above with reference to FIG. 1. Memory device 200 may further include WL driver circuits and Input/Output (IO circuits). The IO circuits may include local IO circuits and global IO circuits.

Memory device 200 further includes a connection cell 210. As discussed in the following sections of the disclosure, connection cell 210 includes a plurality of vertical interconnects to route BL signals in a vertical direction. Connection cell 200 may be located between a top region 202 (or a first region 202) and a bottom region 204 (or a second region 204) of the array. In some examples, top region 202 is also referred to as a top array and bottom region 204 is also referred to as a bottom array. Connection cell 210 may be approximately equal to two cell height (that is, 2H, where H is a cell height).

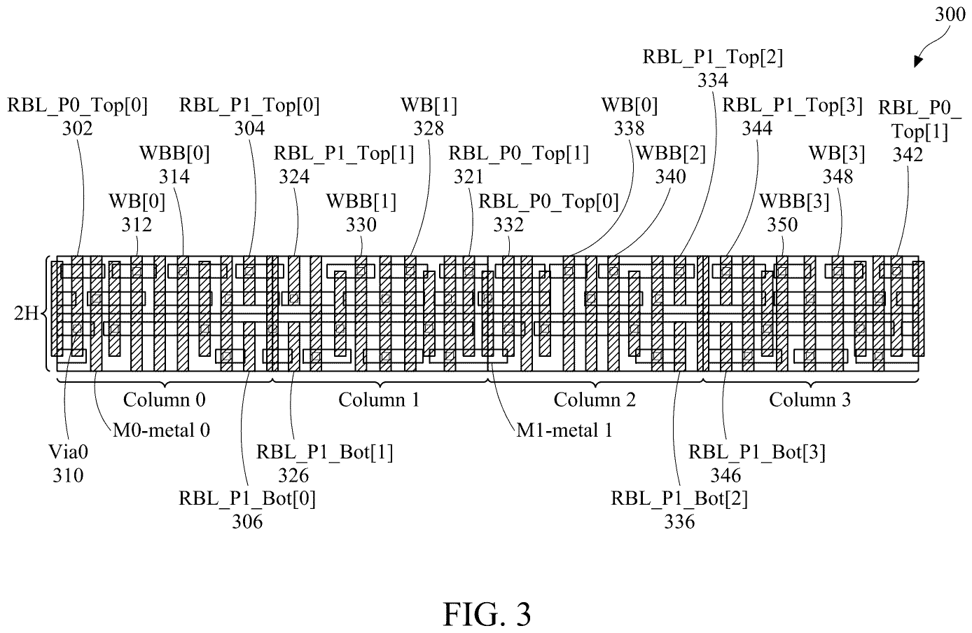

In some examples, connection cell 210 is created by modifying memory cells. For example, connection cell 210 are modified from 2R1W SRAM cells. In a method of forming connection cell 210 from 2R1W SRAM cells, front-end layer patters of the 2R1W SRAM cells are kept as it is. A pattern of back-end layers is modified. For example, via connections and metal layers of 2R1W SRAM cells are modified to form connection cell 210. Layouts for connection cell 210 is discussed in following sections with reference to FIG. 3-7 of the disclosure.

The nth column may include a first plurality of memory cells, for example, a first plurality of 2R1W 10T SRAM cells described above with reference to FIG. 1. Top region 202 of the nth column may include a first portion memory cells of the first plurality of memory cells and bottom region 204 of the nth column may include a second portion memory cells of the first plurality of memory cells. In some implementations, a number of the first portion memory cells is same as a number of the second portion memory cells. In some other implementations, the number of the first portion memory cells is different than the number of the second portion memory cells. For example, the number of the first portion memory cells is greater than the number of the second portion memory cells. In some other examples, the number of the first portion memory cells is lower than the number of the second portion memory cells.

As shown in FIG. 2, the nth column includes read BLs, for example, a nth column first read BL top 215 (that is, RBL_P0_Top[n] 215) and a nth column second read BL top 220 (that is, RBL_P1_Top[n] 220). Each of RBL_P0_Top[n] 215 and RBL_P1_Top[n] 220 are connected to the first portion memory cells of the first plurality of memory cells located in top region 202 of the nth column. In one example, RBL_P0_Top[n] 215 is connected to a first port and be used to perform a read operation through the first port on one of more of the first portion memory cells. Similarly, RBL_P1_Top[n]) 220 is connected to a second port and may be used to perform a read operation through the second port on one of more of the first portion memory cells. In some examples, RBL_P0_Top[n] 215 and RBL_P1_Top[n] 220 are also referred to as a first segment or top segment read BLs.

The nth column further includes a nth column first read BL bottom 225 (that is, RBL_P0_Bot[n] 225) and a nth column second read BL bottom (that is, RBL_P1_Bot[n] 230). Each of RBL_P0_Bot[n] 225 and RBL_P1_Bot[n] 230 are connected to the second portion memory cells of the first plurality of memory cells located in bottom region 204 of the nth column. In one example, RBL_P0_Bot[n] 225 is connected to a first port and is used to perform a read operation through the first port on one of more of the second portion memory cells. Similarly, RBL_P1_Bot[n]) 230 is connected to a second port and is used to perform a read operation through the second port on one of more of the second portion memory cells. In some examples, RBL_P0_Bot[n] 225 and RBL_P1_Bot[n] 230 are also referred to as a second segment or bottom segment read BLs.

The top segment read BLs (that is, RBL_P0_Top[n] 215 and RBL_P1_Top[n] 220) extend from a top of the nth column to connection cell 210 in the first direction. Thus, RBL_P0_Top[n] 215 and RBL_P1_Top[n] 220 do not extend to bottom region 204 of the nth column. The bottom segment read BLs (that is, RBL_P0_Bot[n] 225 and RBL_P1_Bot[n] 230) extend from connection cell 210 to the IO circuits in the first direction. Thus, RBL_P0_Bot[n] 225 and RBL_P1_Bot[n] 230 do not extend to top region 202 of the nth column. In examples, the top segment read BLs and the bottom segment read BLs are formed by segmenting read BLs for the nth column around connection cell 210. In some examples, the top segment read BLs can be longer than the bottom segment read BLs. Thus, the top segment read BLs can be connected to a greater number of memory cells than the bottom segment read BLs.

The nth column further includes flying read BLs, for example, an nth column first flying read BL 235 (that is, FRBL_P0_Top[n] 235) and a nth column second flying read BL 240 (that is, FRBL_P1_Top[n] 240). FRBL_P0_Top[n] 235 is connected to RBL_P0_Top[n] 215 at connection cell 210 and FRBL_P1_Top[n] 240 is connected to RBL_P1_Top[n] 220 at connection cell 210. In some examples, RBL_P0_Top[n] 215 is connected to FRBL_P0_Top[n] 235 for RBL_P0_Top[n] 215 to bypass bottom region 204 of the nth column. Similarly, RBL_P1_Top[n] 220 is connected to FRBL_P1_Top[n] 240 for RBL_P1_Top[n] 220 to bypass bottom region 204 of the nth column. By bypassing bottom region 204 of the nth column, each of RBL_P0_Top[n] 215 and RBL_P1_Top[n] 220 can avoid loading because of the second portion memory cells from bottom region 204, and minimize interference between top region 202 and bottom region 204.

In one example, each of RBL_P0_Bot[n] 225 and RBL_P1_Bot[n] 230 are directly connected to the IO circuits. On the other hand, each of RBL_P0_Top[n] 215 and RBL_P1_Top[n] 220 are connected to the IO circuits through respective flying read BLs (that is, FRBL_P0_Top[n] 235 and FRBL_P1_Top[n] 240 respectively). In examples, the flying read BLs extend from connection cell 210 to the IO circuits in the first direction and do not extend to top region 202 of the nth column.

The read BLs are separated from the flying read BLs in a vertical direction. That is, the read BLs (that is, RBL_P0_Top[n] 215, RBL_P1_Top[n] 220, RBL_P0_Bot[n] 225, and RBL_P1_Bot[n] 230) are formed in a different metal layer than the flying read BLs (that is, FRBL_P0_Top[n] 235 and FRBL_P1_Top[n] 240). For examples, the read BLs are formed in a metal layer zero (that is, a M0 layer) while the flying read BLs are formed in a metal layer four (that is, a M4 layer). In some examples, the flying read BLs may be formed in a metal layer two (that is, a M2 layer) or a higher layer (for example, a metal layer six (that is, a M6 layer)).

The nth column further includes write BLs. For example, the nth column includes an nth write BL 245 (that is, WB[n] 245) and a nth complementary write BL 250 (that is, WBB[n] 250). Each of WB[n] 245 and WBB[n] 250 extend all the way from a top of the array to the bottom in the first direction. Thus, the write BLs are connected to both the first portion of memory cells of top region 202 and the second portion of memory cells of bottom region 204 of the nth column.

In addition, the nth column includes flying write BLs. For example, the nth column includes a nth flying write BL 255 (that is, FWB[n] 255) and a nth flying complementary write BL 260 (that is, FWBB[n] 260). Like the write bit lines, the flying write bit lines (that is, FWB[n] 255 and FWBB[n] 260) extend all the way from a top of the array to the bottom in the first direction.

In examples, the flying write BLs are formed in a different metal layer than the write BLs. For examples, each of WB[n] 245 and WBB[n] 250 are formed in in the metal layer zero (that is, the M0 layer) while the each of FWB[n] 255 and FWBB[n] 260 are formed in the metal layer two (that is, the M2 layer). In some implementations, the flying write BLs may be formed in the metal layer four (that is, the M4 layer) or a metal layer six (that is, the M6 layer).

The write BLs are connected to the flying write BLs, for example, at connection cell 210. In some examples, the write BLs are connected to the flying write BLs at multiple positions such as, in top region 202, in bottom region 204, and connection cell 210. Thus, the write signals are propagated by both, the write BLs and the flying write BLs. This increases the current carrying capacity for the write operations, which reduces signal impedance, minimizes voltage drop, and improves driving strength, especially for longer-distance routing in high-density memory arrays.

For connecting the read BLs with the flying read BLs, RBL_P0_Top [n] 215 and RBL_P1_Top[n] 220 signals are first routed on the M0 layer. These signals are then connected vertically through connection cell 220 to the M4 layer (or higher/lower metal layer). Once routed to the M4 layer, the read BLs from top region 202 do not share any connection with bottom region's 204 read BLs. Top region 202 signals (that is, RBL_P0_Top [n] 215 and RBL_P1_Top[n] 220 signals) continue along the M4 layer all the way to the IO circuits. This routing helps reduce BL loading and minimize interference between top region 202 and bottom region 204.

RBL_P0_Bot[n] 225 and RBL_P1_Bot[n] 230 signals are routed entirely on the M0 layer. Unlike top region 202, RBL_P0_Bot[n] 225 and RBL_P1_Bot[n] 230 signals remain on the M0 layer and directly extend to the IO circuits without passing through connection cell 210 or being elevated to higher metal layers.

Write BL 245 (that is, WB[n] 245) and complementary write BL 250 (that is, WBB[n] 250) signals are transmitted through both the M0 and M2 layers, enabling vertical signal distribution across different regions (that is, top region 202, bottom region 204, and connection cell 210). WB[n] 245 and WBB[n] 250 signal starts on the M0 layer, typically within the array. It is then vertically routed through Via0→M1 layer→Via1→M2 layer. This vertical interconnect can be implemented at various positions, for example, inside top region 202 of the array, inside bottom region 204 of the array, or inside connection cell 210. By using both the M0 layer (that is, a lower metal layer) and the M2 layer (that is, a higher metal layer) for the BL signal propagation, the current-carrying capacity increases, which effectively reduces signal impedance, minimizes voltage drop, and improves driving strength, especially for longer-distance routing in high-density memory arrays.

FIG. 3 illustrates a top view of a first routing layer 300 of connection cell 210. First routing layer 300 illustrates four example columns (that is, column 0, column 1, column 2, and column 3) of an array of memory device 200. It will be apparent that memory device 200 can include more than 4 columns of memory cells. For example, memory device 200 of FIG. 2 may include 32, 64, 128, etc. columns.

First routing layer 300 includes the metal strips of the M0 layer and the M1 layer. For example, as shown in FIG. 3, the M0 layer includes the metal strips of the read BLs for top region 202 and bottom region 202. In one example, the M0 layer includes the metal strips for the 0^{th} column, 0^{th} column top first port read BL 302 (that is, RBL_P0_Top[0] 302), 0^{th} column top second port read BL 304 (that is, RBL_P1_Top[0] 304), and 0^{th} column bottom second port read BL 306 (that is, RBL_P1_Bot[0] 306). In addition, and as shown in FIG. 3, the read BLs for top region 202 of the 0^{th} column (that is, RBL_P0_Top[0] 302 and RBL_P1_Top[0] 304) are connected to the metal strips of M1 layer through via0 310 while the read BLs for bottom region 204 of the 0^{th} column are not. By connecting the read BLs for top region 202 of the 0^{th} column to the metal strips of the M1 layer, the signals from the read BLs are routed to the M1 layer. 0^{th} column further includes the metal strips for the write BLs, for example, 0^{th} column write BL 312 (that is, WB[0] 312) and 0^{th} column complementary write BL 314 (that is, WBB[0] 314). As shown in FIG. 3, the write BLs of the 0^{th} column (that is, WB[0] 312 and WBB[0] 314) are connected to the metal strips of the M1 layer. Thus, the signals from the write BLs are also routed to the M1 layer.

The M0 layer of first routing layer 300 further includes, for the 1^{st} column, the metal stripes for 1^{st} column top first port read BL 322 (that is, RBL_P0_Top[1] 322), 1^{st} column top second port read BL 324 (that is, RBL_P1_Top[1] 324), and 1^{st} column bottom second port read BL 326 (that is, RBL_P1_Bot[1] 326). As shown in FIG. 3A, the read BLs for top region 202 of the 1^{st} column (that is, RBL_P0_Top[1] 322 and RBL_P1_Top[0] 324) are connected to the metal strips of the M1 layer. Thus, the signals from the read BLs of the 1^{st} column are propagated to connected metal strips of the M1 layer.

1^{st} column further includes the write BLs, for example, 1^{st} column write BL 328 (that is, WB[1] 328) and 1^{st} column complementary write BL 330 (that is, WBB[1] 330). As shown in FIG. 3A, the write BLs of the 1^{st} column (that is, WB[1] 328 and WBB[1] 330) are also connected to the metal strips of the M1 layer. Thus, the signals from the write BLs of the 1^{st} column are propagated to connected metal strips of the M1 layer.

The M0 layer of first routing layer 300 further includes, for the 2^{nd} column, 2^{nd} column top first port read BL 332 (that is, RBL_P0_Top[2] 332), 2^{nd} column top second port read BL 334 (that is, RBL_P1_Top[2] 334), and 2^{nd} column bottom second port read BL 336 (that is, RBL_P1_Bot[2] 336). As shown in FIG. 3A, the read BLs for top region 202 of the 2^{nd} column (that is, RBL_P0_Top[0] 332 and RBL_P1_Top[0] 334) are connected to the metal strips of M1 layer. Thus, the signals from the read BLs of the 2^{nd} column are propagated to connected metal strips of the M1 layer.

2^{nd} column further includes write BLs, for example, 2^{nd} column write BL 338 (that is, WB[2] 338) and 2^{nd} column complementary write BL 340 (that is, WBB[2] 340). As shown in FIG. 3, the write BLs of the 2^{nd} column (that is, WB[2] 328 and WBB[2] 340) are also connected to the metal strips of the M1 layer. Thus, the signals from the write BLs of the 2^{nd} column are propagated to connected metal strips of the M1 layer.

The M0 layer of first routing layer 300 further includes, for the 3^{rd} column, 3^{rd} column top first port read BL 342 (that is, RBL_P0_Top[3] 342), 3^{rd} column top second port read BL 344 (that is, RBL_P1_Top[3] 344, and 3^{rd} column bottom second port read BL 346 (that is, RBL_P1_Bot[3] 346). As shown in FIG. 3, the read BLs for top region 202 of the 3^{rd} column (that is, RBL_P0_Top[3] 342 and RBL_P1_Top[3] 344) are connected to the metal strips of M1 layer. Thus, the signal from the read BLs of the 3^{rd} column are propagated to connected metal strips of the M1 layer.

3^{rd} column further includes write BLs, for example, 3^{rd} column write BL 348 (that is, WB[3] 348) and 3^{rd} column complementary write BL 350 (that is, WBB[3] 350). As shown in FIG. 3, the write BLs of the 3^{rd} column (that is, WB[3] 348 and WBB[4] 350) are also connected to the metal strips of the M1 layer. Thus, the signals from the write BLs of the 3^{rd} column are propagated to connected metal strips of the M1 layer.

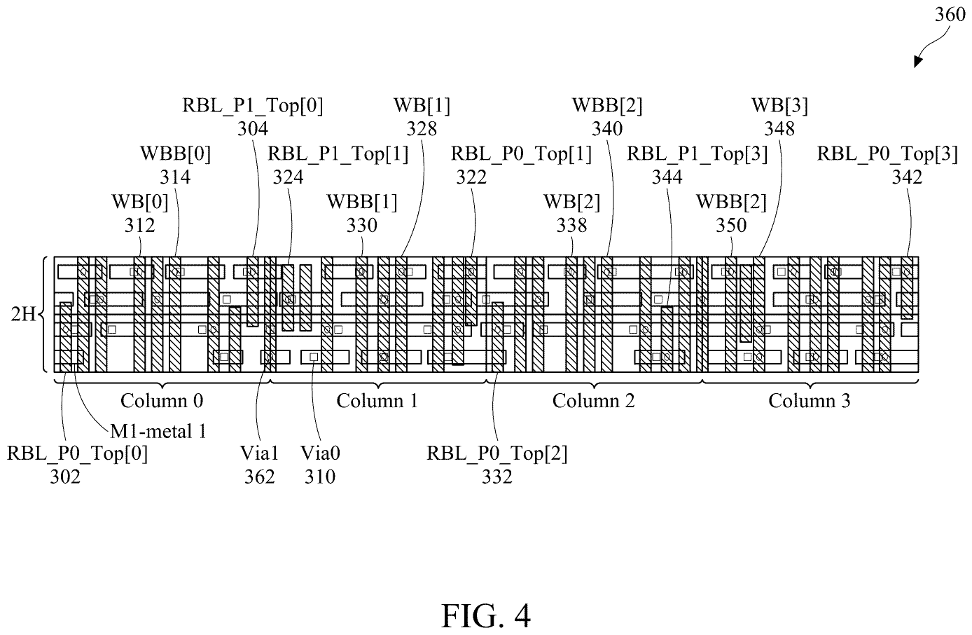

FIG. 4 illustrates a top view of a second routing layer 360 of connection cell 210. In one example, second routing layer 360 connects the metal trips from the M1 layer to the M2 layer. For example, and as shown in FIG. 4, the metal strips with the read BL signals and the write BL signals for each of the 0^{th} column, 1^{st} column, 2^{nd} column, and the third column are connected the metal strips of the M2 layer through Via1 362. This results in the read BL signals and the write BL signals for each of the 0^{th} column, 1^{st} column, 2^{nd} column, and the third column being routed from the M1 layer to the M2 layer in the vertical direction.

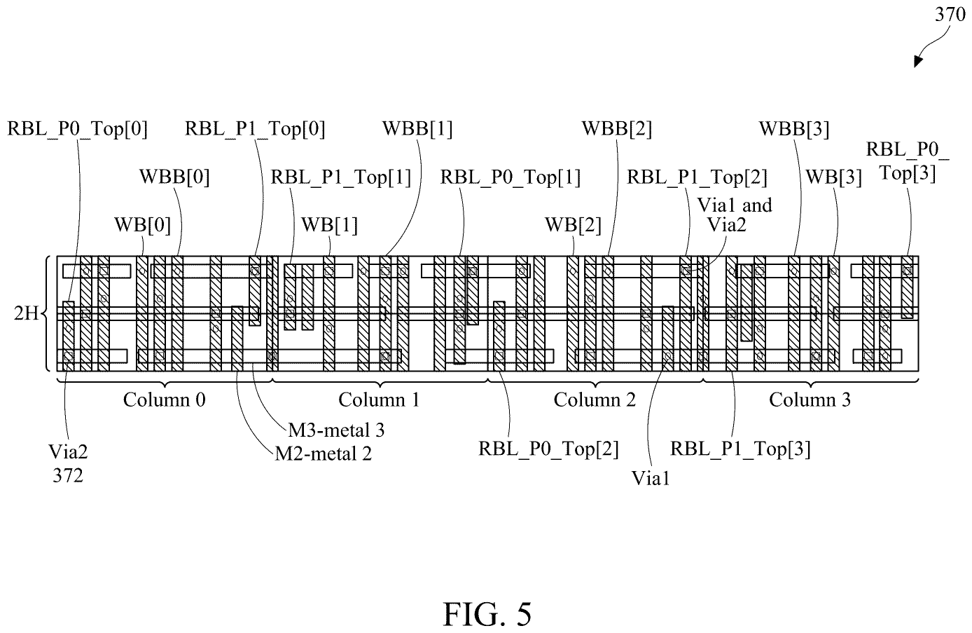

FIG. 5 illustrates a top view of a third routing layer 370 of connection cell 210. In one example, third routing layer 370 connects the metal trips from the M2 layer to metal strips of the M3 layer. For example, and as shown in FIG. 5, the metal strips with the read BL signals for each of the 0^{th} column, 1^{st} column, 2^{nd} column, and the third column are connected the metal strips of the M3 layer through Via2 372. This results in the read BL signals for each of the 0^{th} column, 1^{st} column, 2^{nd} column, and the third column being routed from the metal strips of the M2 layer to the metal strips of the M3 layer in the vertical direction.

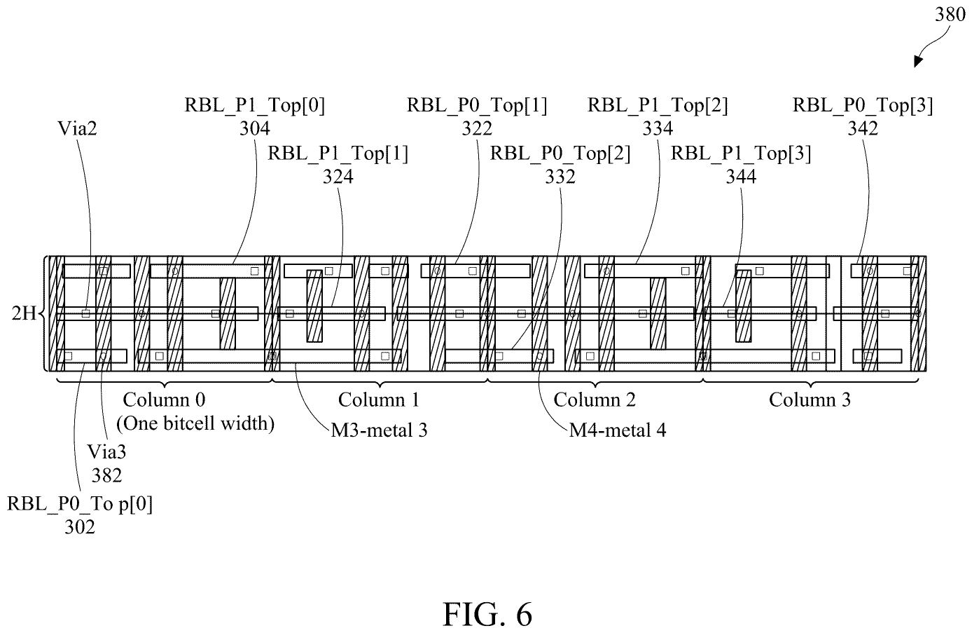

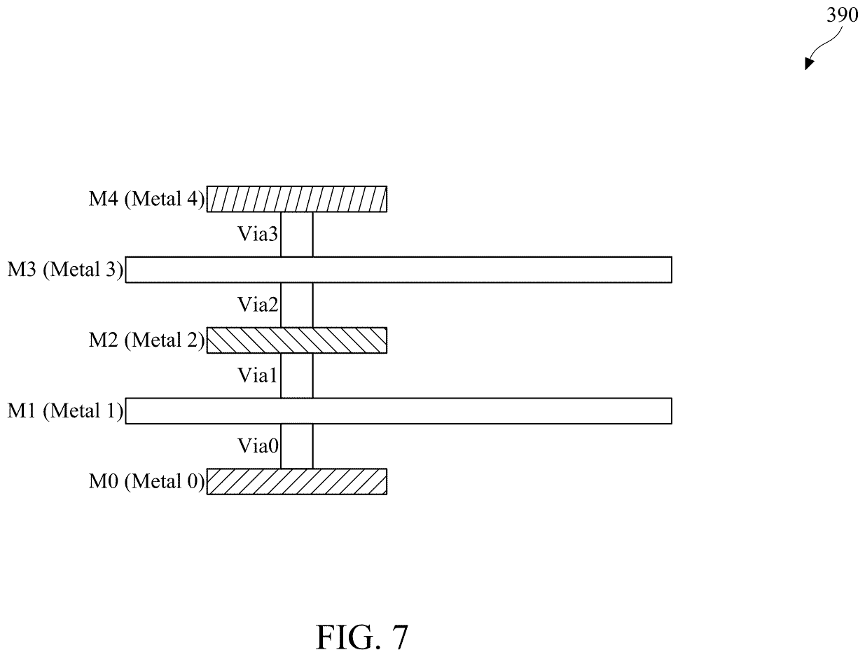

FIG. 6 illustrates a top view of a fourth routing layer 380 of connection cell 210. In one example, fourth routing layer 380 connects the metal trips from the M3 layer to metal strips of the M4 layer. For example, and as shown in FIG. 6, the metal strips with the read BL signals for each of the 0^{th} column, 1^{st} column, 2^{nd} column, and the third column are connected the metal strips of the M4 layer through Via3 382. This results in the read BL signals for each of the 0^{th} column, 1^{st} column, 2^{nd} column, and the third column being routed from the metal strips of the M3 layer to the metal strips of the M4 layer in the vertical direction. FIG. 7 illustrates a cross-section view of connection cell 210. As shown in FIG. 7, the signals are routed vertically from the lower metal layers (for example, the M0 layer) to higher metal layers (for example, the M2 layer for the write BL signals and the M4 layer for the read BL signals).

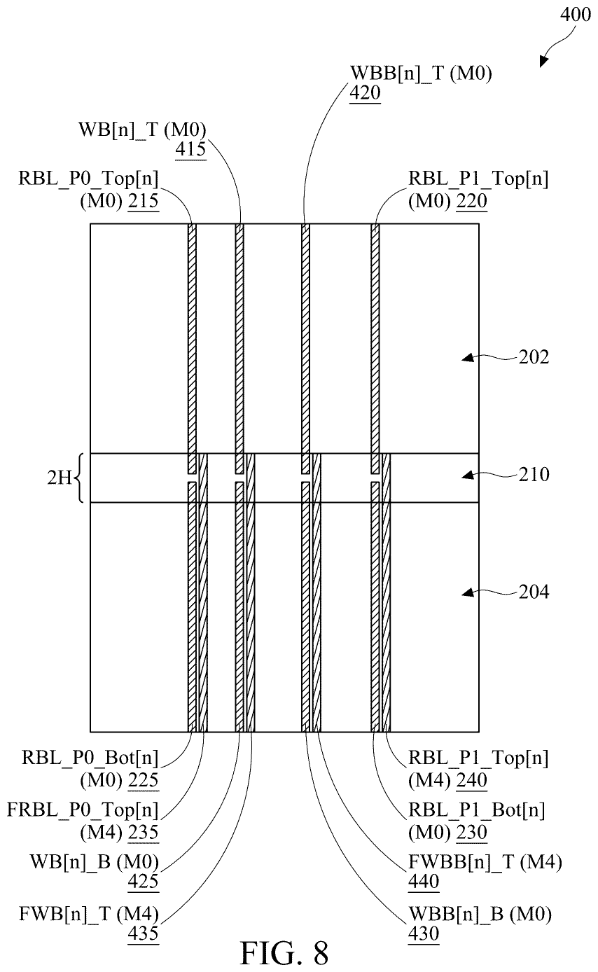

In some examples, the write BLs for a column may also be segmented into two or more segments. FIG. 8 illustrates a nth column of an array of a memory device 400 with segmented write BLs in accordance with example embodiments. For example, memory device 400 includes for example, a nth column write BL top 415 (that is, WB[n]_T 415) and a nth column complementary write BL top 420 (that is, WBB[n]_T 420). Each of WB[n]_T 415 and WBB[n]_T 420 are connected to a first portion memory cells of the first plurality of memory cells located in top region 202 of the nth column. In one example, WB[n]_T 415 and WBB[n]_T 420 are used to perform a write operation in one of more of the first portion memory cells.

The nth column further includes a nth column write BL bottom 425 (that is, WB[n]_B 425) and a nth column complementary write BL bottom (that is, WBB[n]_B 430). Each of WB[n]_B 425 and WBB[n]_B 430 are connected to the second portion memory cells of the first plurality of memory cells located in bottom region 202 of the nth column. In one example, WB[n]_B 425 and WBB[n]_B 430 are used to perform a write operation on one of more of the second portion memory cells.

The top segment write BLs (that is, WB[n]_T 415 and WBB[n]_T 420) extend from a top of the nth column to connection cell 210 in the first direction. Thus, WB[n]_T 415 and WBB[n]_T 420 do not extend to bottom region 204 of the nth column. The bottom segment write BLs (that is, WB[n]_B 425 and WBB[n]_B 430) extend from connection cell 210 to the IO circuits in the first direction. Thus, WB[n]_B 425 and WBB[n]_B 430 do not extend to top region 202 of the nth column. In examples, the top segment write BLs and the bottom segment write BLs are formed by segmenting write BLs for the nth column around connection cell 210. In some examples, the top segment write BLs can be longer than the bottom segment write BLs.

The nth column further includes flying write BLs, for example, an nth column flying read BL 435 (that is, FWB[n]_T 435) and a nth column complementary flying BL 240 (that is, FWWB[n]_T 440). FWB[n]_T 435 is connected to WB[n]_T 415 at connection cell 210 and FWBB[n]_T 440 is connected to WB[n]_T 420 at connection cell 210. In some examples, WB[n]_T 415 is connected to FWB[n]_T 435 for WB[n]_T 415 to bypass bottom region 204 of the nth column. Similarly, WBB[n]_T 420 is connected to FWBB[n]_T 440 for WBB[n]_T 420 to bypass bottom region 204 of the nth column. By bypassing bottom region 204 of the column, each of WB[n]_T 415 and WBB[n]_T 420 can avoid the loading because of the second portion memory cells from bottom region 204 of the nth column, and minimizes interference between top region 202 and bottom region 204.

In one example, each of WB[n]_B 425 and WBB[n]_B 430 are directly connected to the IO circuit. On the other hand, each of WB[n]_T 415 and WBB[n]_T 420 are connected to the IO circuit through respective flying write BLs (that is, FWB[n]_T 435 and FWBB[n]_T 440 respectively). In some examples, the write BLs (that is, WB[n]_T 415, WBB[n]_T 420, WB[n]_B 425, and WBB[n]_B 430) are formed in a different metal layer than the flying write BLs (that is, FWB[n]_T 435 and FWBB[n]_T 440). For example, the write BLs are formed in the metal layer zero (that is, the M0 layer) while the flying write BLs are formed in the metal layer four (that is, the M4 layer). In some examples, the flying write BLs may be formed in the metal layer two (that is, the M2 layer) or a higher metal layer (for example, the M6 layer).

The flying write BLs may be connected to the write BLs in a same way as the read BLs are connected to the flying read BLs as described above with respect to FIGS. 3-7 and hence are being described again for brevity of the disclosure. Nth column 400 of FIG. 8 further includes RBL_P0_Top[n] 215, RBL_P1_Top[n] 220, RBL_P0_Bot[n] 225, RBL_P1_Bot[n] 230, FRBL_P0_Top[n] 235, and FRBL_P1_Top[n] 240.

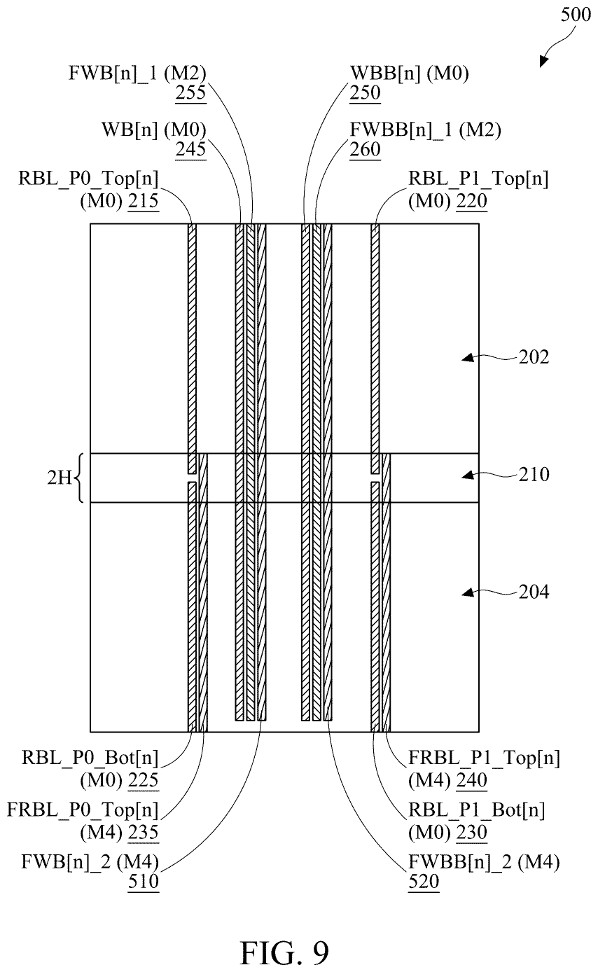

In some examples, each write BLs may be associated with multiple flying write BLs. FIG. 9 illustrates a nth column of an array of a memory device 500 with multiple flying write BLs for each write BL in accordance with example embodiments. As shown in FIG. 8, memory device 500 includes nth column read BLs, that is, RBL_P0_Top[n] 215, RBL_P1_Top[n] 220, RBL_P0_Bot[n] 225, RBL_P1_Bot[n] 230, FRBL_P0_Top[n] 235, and FRBL_P1_Top[n] 240. In addition, memory device 500 includes write BLs, that is, WB[n] 245 and WBB[n] 250.

WB[n] 245 is associated with or connected to multiple flying write BLs, for example, a first flying write BL 255 (that is, FWB[n]_1 255) and a second flying write BL 510 (that is, FWB[n]_2 510). FWB[n]_1 255 extends parallel to WB[n] 245 from top region 202 to the IO of memory device 500. FWB[n]_1 255 is separated from WB[n] 245 in a vertical direction and is formed in a different metal layer than WB[n] 245. For example, FWB[n]_1 255 is formed in the M2 layer and is connected to WB[n] 245 through via0 310 and via1 362. Thus, the write BL signals from WB[n] 245 are propagated in a vertical direction to FWB[n]_1 255.

FWB[n]_2 510 also extends parallel to WB[n] 245 and FWB[n]_1 255 from top region 202 to the IO of memory device 500. In addition, FWB[n]_2 510 is separated from both WB[n] 245 and FWB[n]_1 255 in a vertical direction. FWB[n]_2 510 is formed in a different metal layer than WB[n] 245 and FWB[n]_1 255. For example, FWB[n]_2 510 is formed in the M4 layer and is connected to FWB[n]_1 255 through via2 372 and via3 382. Thus, the write BL signals from WB[n] 245 are propagated in a vertical direction to FWB[n]_2 510 through FWB[n]_1 255.

Similarly, WWB[n] 250 is associated with or connected to multiple complementary flying write BLs, for example, a first complementary flying write BL 260 (that is, FWBB[n]_1 260) and a second complementary flying write BL 520 (that is, FWBB[n]_2 520). FWBB[n]_1 260 extends parallel to WBB[n] 250 from top region 202 to the IO of memory device 500. FWBB[n]_1 260 is separated from WBB[n] 250 in a vertical direction and is formed in a different metal layer than WBB[n] 250. For example, FWBB[n]_1 260 is formed in the M2 layer and is connected to WBB[n] 250 through via0 310 and via1 362. Thus, the complementary write BL signals from WBB[n] 250 are propagated in a vertical direction to FWBB[n]_1 260.

FWBB[n]_2 520 also extends parallel to WBB[n] 250 and FWBB[n]_1 260 from top region 202 to the IO of memory device 500. In addition, FWBB[n]_2 520 is separated from both WBB[n] 250 and FWBB[n]_1 260 in a vertical direction. FWBB[n]_2 520 is formed in a different metal layer than WBB[n] 250 and FWBB[n]_1 260. For example, FWBB[n]_2 520 is formed in the M4 layer and is connected to FWBB[n]_1 515 through via2 372 and via3 382. Thus, the complementary write BL signals from WBB[n] 250 are propagated in a vertical direction to FWBB[n]_2 520 through FWBB[n]_1 260.

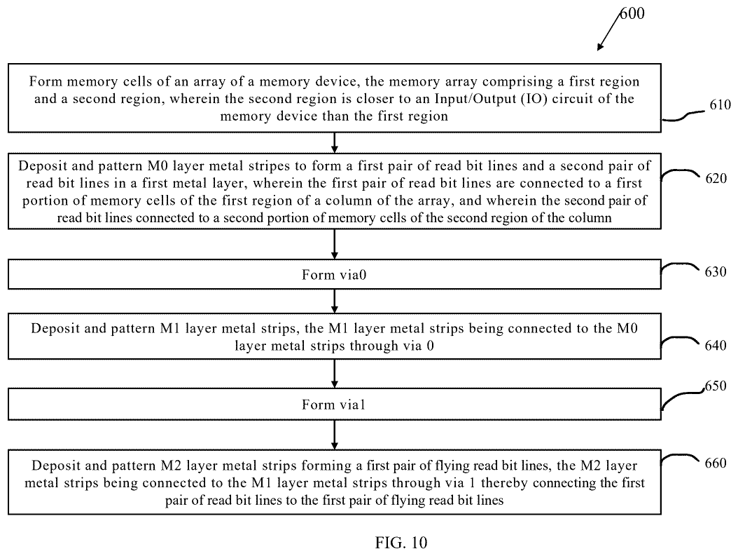

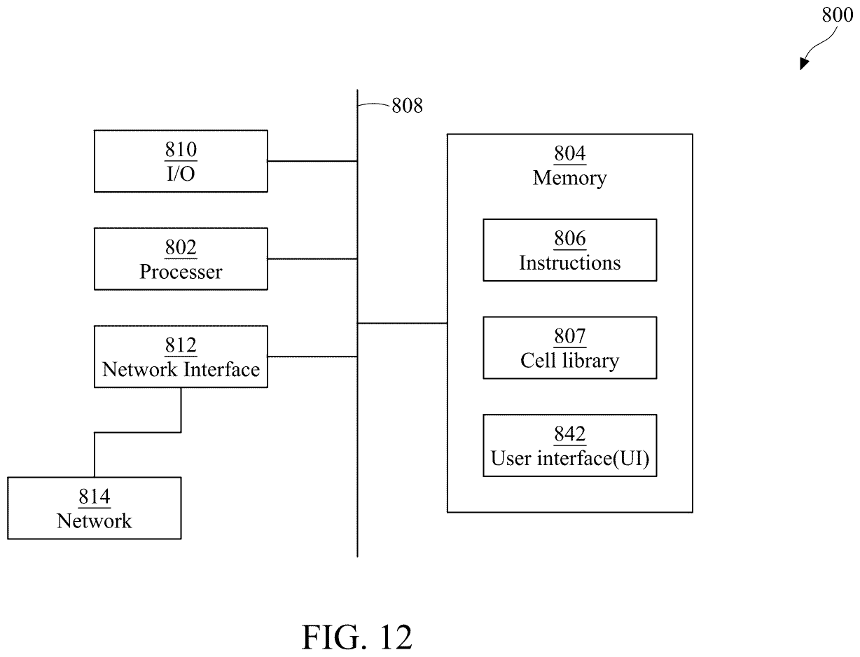

FIG. 10 is a flow diagram illustrating a first method 600 for forming memory device 200, memory device 400, or memory device 500 in accordance with some embodiments. Method 600 may be performed by a layout system 800 as discussed with reference to FIG. 12 of the disclosure. In some examples, method 600 may be stored as instructions on a memory device, which when executed by a processor can cause the processor to perform method 600. Ways to implement the stages of method 600 will be described in greater detail below.

At stage 610 of method 600, memory cells of an array of memory device 200 are formed. For example, an array of the 10T 2R1W memory cells as discussed above with reference to FIG. 1 may be formed. The memory array includes a first region and a second region, the second region being closer to an Input/Output (IO) circuit of the memory device than the first region. For example, the memory cells of both top region 202 and bottom region 204 may be formed.

At stage 620 of method 600, the metal strips of the M0 layer are deposited and patterned to form a first pair of read bit lines and a second pair of bit lines in a first metal layer. As discussed above, the first pair of read bit lines are connected to a first portion of memory cells of the first region of a column of the array and the second pair of read bit lines are connected to a second portion of memory cells of the second region of the column of the array. The metal strips of the M0 layer are deposited and patterned to route initial BL signals from both top region 202 and bottom region 204. For example, the signals from RBL_P0_Top[n] 215, RBL_P1_Top[n] 220, RBL_P0_Bot[n] 225, RBL_P1_Bot[n] 230, WB[n] 245, and WBB[n] 250 are routed to the metal strips of the M0 layer.

At stage 630 of method 600, via0 310 is formed. A first end of via0 310 is connected to the first pair of read bit lines. At stage 640 of method 600, the M1 layer metal strips are deposited and patterned. As discussed above the metal strips of the M1 layer are separated from the M0 layer in a vertical direction. A second end of via0 310 is connected to the M1 layer metal strips thereby connecting the M1 layer metal strips to the first pair of read bit lines.

The M1 layer metal strips are connected to the M0 layer metal strips through via0 310. For example, the metal strips of the M0 layer are connected to the metal strips of the M1 layer to propagate the BL signals in the vertical direction from the M0 layer to the M1 layer.

At stage 650 of method 600, via1 362 is formed. A first end of via1 362 is connected to the M1 layer metal strips. At stage 660 of method 600, the M2 layer metal strips are deposited and patterned. As discussed above the metal strips of the M2 layer are separated from the M1 layer in a vertical direction.

The M2 layer metal strips are connected to the M1 layer metal strips through via1 362 thereby connecting the first pair of read bit lines to the first pair of flying read bit lines. For example, the metal strips of the M1 layer are connected to the metal strips of the M2 layer to propagate the BL signals in the vertical direction from the M1 layer to the M2 layer. In examples, the higher layers (for example, the M3 layer, M4 layer, etc.) are formed by repeating stages 650 and 660 of method 600.

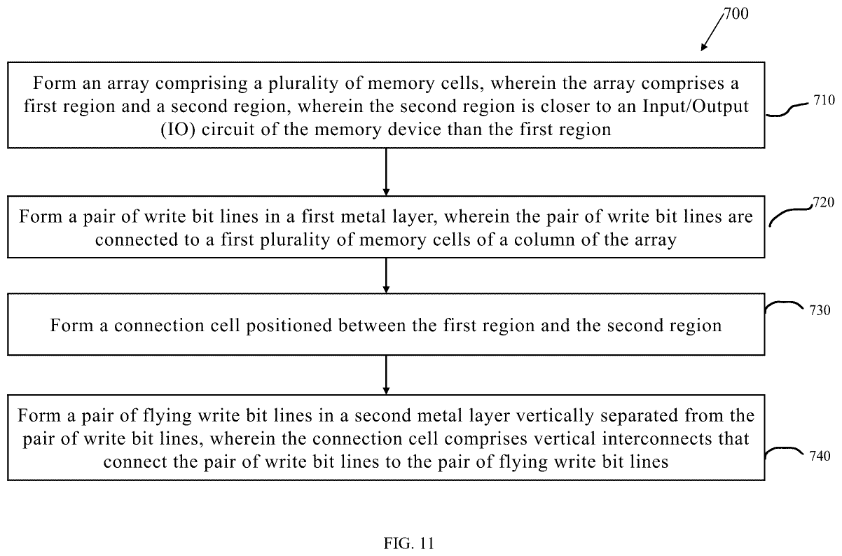

FIG. 11 is a flow diagram illustrating a second method 700 for forming any of memory device 200, memory device 400, or memory device 500 in accordance with some embodiments. Method 700 may be performed by layout system 800 as discussed with reference to FIG. 12 of the disclosure. In some examples, method 700 may be stored as instructions on a memory device, which when executed by a processor can cause the processor to perform method 700. Ways to implement the stages of method 700 will be described in greater detail below.

At stage 710 of method 700, an array having a plurality of memory cells is formed. The array includes first region 202 and a second region 204. Second region 204 is closer to an IO circuit of memory device 200 than first region 202. For example, an array of the 10T 2R1W memory cells as discussed above with reference to FIG. 1 may be formed.

At stage 720 of method 700, a pair of write BLs are formed in a first metal layer. The pair of write BLs are connected to a first plurality of memory cells of a column of the array. For example, write BL 245 (that is, WB[n] 245) and complementary write BL 250 (that is, WBB[n] 250) are formed in the M0 layer.

At stage 730 of method 700, connection cell 210 positioned between first region 202 and second region 204 is formed. Connection cell 210 includes vertical interconnects that may connect the pair of write BLs to a pair of flying write BLs.

At stage 740 of method 700, a pair of flying write BLs are formed in a second metal layer vertically separated from the pair of write BLs. For example, flying write BL 255 (that is, FWB[n] 255) and complementary flying write BL 260 (that is, FWBB[n] 260) are formed in the M2 layer. The flying write BLs are connected to the write BLs through connection cell 210. In some examples, and as discussed above, the write BLs are connected to the flying write BLs at multiple positions such as, in top region 202, in bottom region 204, and connection cell 210. Thus, the write signals are propagated by both, the write BLs and the flying write BLs.

The processes disclosed herein speed up read access time for the array and reduced power consumption during the read operation. In addition, and as discussed above, by connecting the BLs with flying BLs helps in reducing BL loading and minimizes interference between the top and bottom regions of the array. The hierarchical metal routing (for example, the M2 layer or M4 layer routing) of the flying BLs can allow for greater routing flexibility, particularly in large memory macros where signal congestion is high.

FIG. 12 is a block diagram of a layout system 800, in accordance with some embodiments. Methods described herein of memory device 200, memory device 400, or memory device 500 in accordance with one or more embodiments are implementable, for example, using layout system 800. In some embodiments, layout system 800 is a general-purpose computing device including a hardware processor 802 and a non-transitory, computer-readable storage medium 804. Storage medium 804, amongst other things, is encoded with, i.e., stores, computer program code 806, i.e., a set of executable instructions. Execution of instructions 806 by hardware processor 802 represents (at least in part) an EDA tool which implements a portion or all of method 600 and method 700 for forming memory device 200 described above with respect to FIG. 10 and FIG. 11 respectively.

Processor 802 is electrically coupled to computer-readable storage medium 804 via a bus 808. Processor 802 is also electrically coupled to an I/O interface 810 by bus 808. A network interface 812 is also electrically connected to processor 802 via bus 808. Network interface 812 is connected to a network 814, so that processor 802 and computer-readable storage medium 804 are capable of connecting to external elements via network 814. Processor 802 is configured to execute computer program code 806 encoded in computer-readable storage medium 804 in order to cause layout system 800 to be usable for performing a portion or all of the noted processes and/or methods. In one or more embodiments, processor 802 is a Central Processing Unit (CPU), a multi-processor, a distributed processing system, an Application Specific Integrated Circuit (ASIC), and/or a suitable processing unit.

In one or more embodiments, computer-readable storage medium 804 is an electronic, magnetic, optical, electromagnetic, infrared, and/or a semiconductor system (or apparatus or device). For example, computer-readable storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 804 includes a compact disk-read only memory (CD-ROM), a compact disk-read/write (CD-R/W), and/or a digital video disc (DVD).

In one or more embodiments, computer-readable storage medium 804 stores computer program code 806 configured to cause layout system 800 (where such execution represents (at least in part) the EDA tool) to be usable for performing a portion or all of the noted processes and/or methods. In one or more embodiments, computer-readable storage medium 804 also stores information which facilitates performing a portion or all of the noted processes and/or methods. In one or more embodiments, computer-readable storage medium 804 stores cell library 807 of memory cells including such memory cells as disclosed herein with respect to FIG. 1.

Layout system 800 includes I/O interface 810. I/O interface 810 is coupled to external circuitry. I/O interface 810 may include a keyboard, keypad, mouse, trackball, trackpad, touchscreen, and/or cursor direction keys for communicating information and commands to processor 802.

Layout system 800 also includes network interface 812 coupled to processor 802. Network interface 812 allows layout system 800 to communicate with network 814, to which one or more other computer systems are connected. Network interface 812 may include wireless network interfaces or wired network interfaces.

Layout diagram generation system 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. Layout system 800 is configured to receive information related to a UI through I/O interface 810. The information is stored in computer-readable medium 804 as User Interface (UI) 842.

In accordance with some embodiments, a memory device comprises: an array comprising a plurality of columns, wherein each column of the plurality of columns comprises: a first pair of read bit lines connected to a first portion of memory cells of a top region of the column, a second pair of read bit lines connected to a second portion of memory cells of a bottom region of the column, and a first pair of flying read bit lines; and a connection cell positioned between the top region and the bottom region, wherein connection cell comprises vertical interconnects the connect the first pair of read bit lines to the first pair of flying read bit lines.

In accordance with some embodiments, a memory device comprises: an array comprising a first region and a second region, wherein the second region is closer to an Input/Output (IO) circuit of the memory device than the first region; a first pair of read bit lines connected to a first portion of memory cells of the first region of a column of the array; a second pair of read bit lines connected to a second portion of memory cells of the second region of the column; a first pair of flying read bit lines; and a connection cell positioned between the top region and the bottom region, wherein connection cell comprises vertical interconnects the connect the first pair of read bit lines to the first pair of flying read bit lines.

In accordance with example embodiments, a method of forming a memory device, comprises: forming an array comprising a plurality of memory cells, wherein the array comprises a first region and a second region, wherein the second region is closer to an Input/Output (IO) circuit of the memory device than the first region; forming a pair of write bit lines in a first metal layer, wherein the pair of write bit lines are connected to a first plurality of memory cells of a column of the array; forming a pair of flying write bit lines in a second metal layer vertically separated from the pair of write bit lines; and forming a connection cell positioned between the first region and the second region, wherein connection cell comprises vertical interconnects the connect the pair of write bit lines to the pair of flying write bit lines.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device comprising:
an array comprising a plruality of columns, wherein each column of the plurality of columns comprises:
a first pair of read bit lines connected to a first portion of memory cells of a top region of the column,
a second pair of read bit lines connected to a second portion of memory cells of a bottom region of the column, and
a first pair of flying read bit lines; and
a connection cell positioned between the top region and the bottom region, wherein the connection cell comprises vertical interconnects the connect the first pair of read bit lines to the first pair of flying read bit lines.

2. The memory device of claim 1, wherein each of the first pair of bit lines and the second pair of bit lines are formed in a first metal layer.

3. The memory device of claim 2, wherein the first pair of flying bit lines are formed in a second metal layer, and wherein the second metal layer is different from the first metal layer.

4. The memory device of claim 2, wherein the first pair of flying bit lines are formed in a metal layer four, and wherein each of the first pair of bit lines and the second pair of bit lines are formed in a metal layer zero.

5. The memory device of claim 1, wherein the connection cell is formed from two read one write (2R1W) 10-Transistor (10T) Static Random Access Memory (SRAM) cells.

6. The memory device of claim 1, wherein the first portion of memory cells and the second portion of memory cells comprises two read one write (2R1W) 10-Transistor (10T) Static Random Access Memory (SRAM) cells.

7. The memory device of claim 1, further comprising a pair of write bit lines connected to the first portion of memory cells and the second portion of memory cells of the column.

8. The memory device of claim 7, further comprising a pair of flying write bit lines, wherein the pair of flying bit lines are connected to the pair of write bit lines through the vertical interconnects of the connection cell.

9. A memory device comprising:
an array comprising a first region and a second region, wherein the second region is closer to an Input/Output (IO) circuit of the memory device than the first region;
a first pair of read bit lines connected to a first portion of memory cells of the first region of a column of the array;
a second pair of read bit lines connected to a second portion of memory cells of the second region of the column;
a first pair of flying read bit lines; and
a connection cell positioned between the first region and the second region, wherein the connection cell comprises vertical interconnects the connect the first pair of read bit lines to the first pair of flying read bit lines.

10. The memory device of claim 9, wherein the connection cell is formed from two read one write (2R1W) 10-Transistor (10T) Static Random Access Memory (SRAM) cells.

11. The memory device of claim 9, wherein the connection cell comprises a first routing layer, and wherein the first routing layer vertically connects the first pair of read bit lines from a metal layer zero to a metal layer one two though via0.

12. The memory device of claim 11, wherein the connection cell further comprises a second routing layer, and wherein the second routing layer vertically connects the metal layer one to a metal layer two though via1.

13. The memory device of claim 9, wherein the first pair of bit lines do not extend to the second region.

14. The memory device of claim 9, wherein the first pair of bit lines are formed in a first metal layer, wherein the first pair of flying bit lines are formed in a second metal layer, and wherein the second metal layer is separated from the first metal layer in a vertical direction.

15. The memory device of claim 9, wherein the first pair of bit lines are formed in a metal layer zero, and wherein the first pair of flying bit lines are formed in a metal layer four.

16. The memory device of claim 9, further comprising a pair of write bit lines connected to the first portion of memory cells and the second portion of memory cells of the column.

17. The memory device of claim 16, further comprising a pair of flying write bit lines, wherein the pair of flying bit lines are connected to the pair of write bit lines through the vertical interconnects of the connection cell.

18. A method of forming a memory device, the method comprising:
forming a plurality of memory cells of an array, wherein the array comprises a first region and a second region, wherein the second region is closer to an Input/Output (IO) circuit of the memory device than the first region;
forming a pair of write bit lines in a first metal layer, wherein the pair of write bit lines are connected to a first plurality of memory cells of a column of the array;
forming a connection cell positioned between the first region and the second region; and
forming a first pair of flying write bit lines in a second metal layer vertically separated from the pair of write bit lines, wherein the connection cell comprises vertical interconnects that connect the pair of write bit lines to the first pair of flying write bit lines.

19. The method of claim 18, further comprising:
forming a second pair of flying write bit lines in a second metal layer vertically separated from the first pair of flying write bit lines.

20. The method of claim 19, wherein the first pair of flying write bit lines are formed in a metal layer two, and wherein the second pair of flying write bit lines are formed in a metal layer four.
